(19) United States
(12) Patent Application Publication
(10) Pub. No.: US 2025/0160078 A1
(43) Pub. Date: May 15, 2025

(54) OPTOELECTRONIC COMPONENT AND METHOD FOR PRODUCING AN OPTOELECTRONIC COMPONENT

(71) Applicant: ams-OSRAM International GmbH, Regensburg (DE)

(72) Inventors: Andreas REITH, Steinach (DE); Gunnar PETERSEN, Regensburg (DE); Daniel RICHTER, Bad Abbach (DE)

(21) Appl. No.: 18/835,127

(22) PCT Filed: Dec. 12, 2022
(86) PCT No.: PCT/EP2022/085417

§ 371 Date: Aug. 1, 2024

(30) Foreign Application Priority Data
Feb. 2, 2022 (DE) 10 2022 102 431.8

(51) Int. Cl. H10H 20/856; H10H 20/01

(52) U.S. Cl. CPC H10H 20/856; H10H 20/0363

(57) ABSTRACT

An optoelectronic component includes a carrier, at least one optoelectronic semiconductor chip, which is arranged on the carrier, and a housing which comprises a molded body. The housing at least partially surrounds the optoelectronic semiconductor chip. A reflective layer is arranged on at least one side surface of the optoelectronic semiconductor chip, and the carrier includes vias.

An optoelectronic component and a method for producing an optoelectronic component are provided.

Optoelectronic components, such as radiation emitting or radiation receiving components, for example light emitting diodes (LEDs) or detectors, are used in many applications. An optoelectronic component comprises, for example, a carrier, an optoelectronic semiconductor chip with an active region and a housing. One function of the housing is to provide a greater robustness and a longer service life of the optoelectronic component. Housings that are irradiated with ultraviolet (UV) radiation often suffer from a shortened service life as the UV radiation attacks the housing.

A task to be solved is to specify an optoelectronic component which can be operated particularly efficiently. A further task is to specify a method for producing an optoelectronic component that can be operated particularly efficiently.

The tasks are solved by the subject-matter of the independent patent claims. Advantageous configurations and further developments are given in the dependent claims.

According to at least one embodiment of the optoelectronic component, the optoelectronic component comprises a carrier. The carrier can, for example, consist of a growth substrate or include a growth substrate. The carrier may comprise a ceramic material or the carrier may be a ceramic substrate.

Alternatively, the carrier may be another mechanically supporting component of the optoelectronic component. Furthermore, the carrier can comprise an electrical contacting. With this, the optoelectronic component can be contacted electrically from the rear side, for example. Thereby, a part of the electrical contacting can be arranged on the underside of the carrier. This part of the electrical contacting represents an electrical rear contacting of the optoelectronic component. A further part of the electrical contacting can be arranged on the top side of the carrier. The parts of the electrical contacting on the top side and underside of the carrier are electrically conductively connected to each other. Furthermore, the carrier can also comprise a coating.

The carrier can be a three-dimensional body which, for example, comprises at least approximately the shape of a cuboid, a cylinder or a disc. The carrier can comprise a main extension plane. The main extension plane of the carrier runs parallel to a surface, for example a cover surface, of the carrier.

According to at least one embodiment of the optoelectronic component, the optoelectronic component comprises at least one optoelectronic semiconductor chip which is arranged on the carrier. The optoelectronic semiconductor chip may, for example, be a luminescent diode chip, for instance a light-emitting diode chip. The optoelectronic semiconductor chip can be designed to emit electromagnetic radiation during operation. For example, the optoelectronic semiconductor chip can emit electromagnetic radiation in the ultraviolet range. This irradiation can in particular take place in a direction in which the optoelectronic semiconductor chip is not surrounded by a housing or the carrier. Alternatively, the optoelectronic semiconductor chip can also be suitable for receiving electromagnetic radiation. The optoelectronic semiconductor chip can be arranged on the part of the electrical contacting of the carrier which is arranged on the top side of the carrier. The optoelectronic semiconductor chip is thereby electrically contacted.

According to at least one embodiment of the optoelectronic component, the optoelectronic component comprises a housing which comprises a molded body, wherein the housing at least partially surrounds the optoelectronic semiconductor chip. For example, the molded body can be formed on the optoelectronic semiconductor chip by casting, injection molding or pressing. The molded body can comprise a molding compound or consist entirely of the molding compound. The molding compound can be, for example, but not necessarily exclusively, a polymer, epoxy or silicone. That the housing at least partially surrounds the optoelectronic semiconductor chip can mean that the housing at least partially surrounds the optoelectronic semiconductor chip in lateral directions, which run parallel to the main extension plane of the carrier. This can mean that the housing extends at least in places around the optoelectronic semiconductor chip in lateral directions. The housing can completely surround the optoelectronic semiconductor chip in lateral directions. The housing can be arranged spaced apart from the optoelectronic semiconductor chip. Furthermore, due to the housing a mechanically robust optoelectronic component can be enabled.

According to at least one embodiment of the optoelectronic component, a reflective layer is arranged on at least one side surface of the optoelectronic semiconductor chip. The reflective layer can be optically reflective. The reflective layer may be a layer with a reflectivity of more than 40%, for example more than 50%, in particular more than 80%, preferably more than 90% and particularly preferably more than 95%, in particular almost 100%. This reflectivity can, for example, be achieved for a large range of the spectrum of the electromagnetic radiation or alternatively only for certain wavelength ranges. Alternatively or additionally, the reflective layer can comprise a low transmittance. The transmittance can be at most 20%, for example at most 10% or in particular at most 1%. This transmittance can be achieved, for example, for a large range of the spectrum of the electromagnetic radiation or alternatively only for certain wavelength ranges. A wavelength range can, for example, be the UV-C range, i.e. a wavelength range of 100 nm-280 nm. For this wavelength range, the reflective layer can comprise one of the aforementioned reflectivities and/or transmittances.

The reflective layer can consist of a metal or contain a metal. The reflective layer can, for example, comprise gold, preferably rhodium and particularly preferably aluminum. The reflective layer can consist of at least 90% of its volume of gold, rhodium or aluminum.

Alternatively, the reflective layer can be a mirror, for example. The reflective layer could therefore comprise a dielectric mirror, a hybrid mirror or a multilayer mirror, for example. A reflective side of the mirror can in particular face the optoelectronic semiconductor chip.

The reflective layer can comprise a thickness of at least 20 nm, for example at least 50 nm. For example, the reflective layer can comprise a thickness of at least 1 μm.

The at least one side surface designates a surface of the optoelectronic semiconductor chip. The side surface is therefore a part of the optoelectronic semiconductor chip. The at least one side surface is preferably a surface of the optoelectronic semiconductor chip which is arranged perpendicularly or transversely to the main extension plane of the carrier. Furthermore, the side surface is a surface from which no emission of electromagnetic radiation is intended.

According to at least one embodiment, the optoelectronic component comprises a carrier, at least one optoelectronic semiconductor chip, on at least one side surface of which a reflective layer is arranged, and which is arranged on the carrier, and a housing, which comprises a molded body and at least partially surrounds the optoelectronic chip.

The optoelectronic component described here is based, among other things, on the idea that a higher luminance can be achieved due to the reflective layer, as a lower proportion of the radiation emitted by the optoelectronic semiconductor chip is absorbed by the surrounding housing and can instead be emitted in a preferred direction of radiation. The side emission of the optoelectronic semiconductor chip, which cannot usually be used in an application, is thus minimized. The preferred radiation direction or irradiation direction can be a direction that runs perpendicular to the main extension plane of the carrier. Due to the reflective layer also the housing material can at least partially be protected from irradiation with the emitted electromagnetic radiation. Typical housing materials can be damaged by electromagnetic radiation, in particular UV radiation. Such a damage is at least reduced by the use of the reflective layer. The housing material can thus, for example, be at least partially protected from UV radiation emitted by the optoelectronic semiconductor chip. Thereby, the service life of the optoelectronic component can be extended and it can thus be operated efficiently.

According to at least one embodiment of the optoelectronic component, the reflective layer is at least in places in direct contact with the optoelectronic semiconductor chip. The reflective layer can be at least in places in direct contact with the optoelectronic semiconductor chip on the side surface. The reflective layer can be in direct contact with the optoelectronic semiconductor chip on the entire side surface. This means that the reflective layer can completely cover the side surface. Due to the direct contact of the reflective layer with the optoelectronic semiconductor chip, the component size can be minimized, or at least reduced. Thereby, also a higher luminance can be achieved.

According to at least one embodiment of the optoelectronic component, the at least one side surface of the optoelectronic semiconductor chip on which the reflective layer is arranged faces at least a part of the housing. The optoelectronic semiconductor chip can comprise at least one side surface. The housing can at least partially mold the optoelectronic semiconductor chip. Thus, the housing can be arranged at least partially adjacent to at least one side surface of the optoelectronic semiconductor chip. The reflective layer can also be arranged on this at least one side surface. Facing a part of the housing hereby means that the side surface of the optoelectronic semiconductor chip with the reflective layer runs parallel to the housing in places, wherein only the reflective layer is arranged between the optoelectronic semiconductor chip and the housing. Facing can thereby also mean that the side surface with the reflective layer applied to the optoelectronic semiconductor chip is in direct contact with the housing. One idea of the invention is that materials that are not highly UV-resistant can also be used as a housing material, for example as a molding compound. An advantage of the above embodiment is that the radiation emitted by the optoelectronic semiconductor chip is reflected by the reflective layer and thus does not radiate onto the housing or penetrate the housing material in these areas. This protects the housing from damage caused by the emitted electromagnetic radiation.

According to at least one embodiment of the optoelectronic component, the reflective layer completely covers the at least one side surface of the optoelectronic semiconductor chip. The reflective layer may also completely cover all side surfaces of the optoelectronic semiconductor chip. An advantage of the above embodiment is that the radiation emitted by the optoelectronic semiconductor chip is reflected by the reflective layer on the at least one side surface particularly efficiently, namely over the entire side surface, and thus does not radiate onto the housing or penetrate into the housing material. Thereby the housing is protected by damages by the emitted electromagnetic radiation.

According to at least one embodiment of the optoelectronic component, the at least one side surface of the optoelectronic semiconductor chip extends transversely or perpendicularly to the main extension plane of the carrier. The side surface can comprise a main extension plane which extends transversely or perpendicularly to the main extension plane of the carrier. The side surface is thus a surface from which emission of electromagnetic radiation is not intended. Advantageously, radiation emerging from the side surface is reflected at the reflective layer.

According to at least one embodiment of the optoelectronic component, the optoelectronic semiconductor chip comprises a further reflective layer on at least one further side surface which extends transversely or perpendicularly to the main extension plane of the carrier. The further side surface is a different side surface of the optoelectronic semiconductor chip, thus a different surface of the optoelectronic semiconductor chip than the at least one side surface. The further side surface otherwise comprises the same properties as the side surface. The further reflective layer is arranged on the further side surface of the optoelectronic semiconductor chip. Furthermore, the further reflective layer can comprise the same properties as the reflective layer. An advantage of this embodiment is that the radiation emitted by the optoelectronic semiconductor chip is reflected particularly efficiently, as also on the further side surface a reflective layer is arranged.

According to at least one embodiment of the optoelectronic component, the reflective layer is arranged on at least one further side surface of the optoelectronic semiconductor chip, which extends transversely or perpendicularly to the main extension plane of the carrier. Thereby, the reflective layer can cover the further side surface partially, but also completely. Furthermore, the reflective layer can also be arranged on all further side surfaces. Thus, a larger proportion of the radiation emitted by the optoelectronic semiconductor chip on its side surfaces is reflected. This protects the housing from being damaged by the radiation.

According to at least one embodiment of the optoelectronic component, the reflective layer is at least in places in direct contact with the housing. The reflective layer can be in direct contact with the housing at least in places on the side surface of the optoelectronic semiconductor chip. The reflective layer can, for example, also be in direct contact with the housing over an entire side surface, for example also over all side surfaces of the optoelectronic semiconductor chip. An idea of the optoelectronic component described herein is to enable a more compact design. This can, for example, achieve the dimensions of a chip scale package. As a result, more optoelectronic components can be arranged on a consistently large area, which can increase the luminance. Due to the direct contact of the reflective layer with the housing, the optoelectronic component can have a compact design and the stability of the reflective layer can also be improved.

According to at least one embodiment of the optoelectronic component, the reflective layer comprises a metal, aluminum, rhodium and/or a mirror. These materials have a high reflectivity in the UV range. Thus, a reflective layer made of one of these materials can, for example, reflect emitted UV radiation particularly efficiently.

According to at least one embodiment of the optoelectronic component, the optoelectronic semiconductor chip is designed to emit electromagnetic radiation in the ultraviolet range during operation. The optoelectronic semiconductor chip can therefore be, for example, a UV LED, a UV laser or a UV sapphire flip chip.

An idea of the optoelectronic component described here is to extend the service life of the housing, which can be produced, for example, by a molded body made of UV-instable materials, by slowing down, preventing or almost preventing the degeneration triggered by the emitted radiation in the UV range by the fact that the reflective layer is arranged between the optoelectronic semiconductor chip and the housing.

According to at least one embodiment of the optoelectronic component, the reflective layer comprises a reflectivity of at least 40%, at least 50% or at least 80% in the UV range. A reflectivity of the reflective layer of at least 40%, at least 50% or at least 80% provides a better protection of the housing material against UV radiation, as the UV radiation that impinges on the reflective layer is reflected and does not penetrate into the housing. In addition, the proportion of UV radiation emitted in the direction of radiation is increased.

According to at least one embodiment of the optoelectronic component, the reflective layer comprises a transmittance of at most 20%, for example at most 10% or in particular at most 1%. Another term for transmittance is transmissivity. An advantage of this embodiment is that, due to the low transmission of the reflective layer, the UV radiation that impinges on the reflective layer can be at least partially reflected and/or absorbed by the reflective layer. Thus, the housing material can be better protected from UV radiation. According to at least one embodiment of the optoelectronic component, the carrier is electrically contactable on the side facing away from the optoelectronic semiconductor chip. Electrically contactable can mean that the carrier comprises at least one electrical contact on the side facing away from the optoelectronic semiconductor chip. The electrical contact can be electrically connected to an electrical contact of the optoelectronic semiconductor chip. The carrier can comprise vias that extend through the carrier. The vias can connect a bottom side of the carrier to an upper side of the carrier, for example perpendicularly or transversely to the main extension plane of the carrier. Advantageously, the optoelectronic semiconductor chip can thus be contacted electrically via the underside of the carrier. This means that the optoelectronic component can be surface mountable. In this case, no electrical contacting of the optoelectronic semiconductor chip on its radiation exit side is required. This means that the entire top side of the optoelectronic semiconductor chip can be used for radiation emission. This enables efficient operation of the optoelectronic component.

According to at least one embodiment of the optoelectronic component, an electrically insulating filling material is arranged between the carrier and the optoelectronic semiconductor chip. The filling material prevents a short circuit of the optoelectronic component via the reflective layer by filling the gaps formed by the electrical contacting and the optoelectronic semiconductor chip. One feature of the filling material is that it is in particular electrically insulating. The filling material is a filling compound which may, for example, consist of an epoxy or contain an epoxy.

The filling material can be flush with the edges of the optoelectronic semiconductor chip. Alternatively, the filling material can, for example, also extend beyond the edges of the optoelectronic semiconductor chip or partially cover a side surface of the optoelectronic semiconductor chip.

For example, the reflective layer is in direct contact with the carrier and the filling material.

According to at least one further embodiment of the optoelectronic component, the carrier comprises a ceramic material and a via, and the optoelectronic semiconductor chip is a sapphire flip chip. The sapphire flip chip can be designed to emit electromagnetic radiation in the UV-C range. In particular, the reflective layer, which may contain aluminum, can be applied directly to the side surfaces of the sapphire flip chip. The housing can surround the sapphire flip chip and, thereby, be directly adjacent to the reflective layer.

Further, a method for producing an optoelectronic component is provided. The optoelectronic component is preferably producible by a method described herein. In other words, all features disclosed for the optoelectronic component are also disclosed for the method for producing an optoelectronic component and vice versa.

According to at least one embodiment of the method for producing an optoelectronic semiconductor chip, the method comprises a method step in which a carrier is provided.

According to at least one embodiment of the method for producing an optoelectronic semiconductor chip, the method comprises a method step in which an optoelectronic semiconductor chip is applied on the carrier. The optoelectronic semiconductor chip can be attached to the carrier, for example by soldering or gluing.

According to at least one embodiment of the method for producing an optoelectronic semiconductor chip, the method comprises a method step in which a reflective layer is applied to at least one side surface of the optoelectronic semiconductor chip. Thereby, the reflective layer can also be in direct contact with the carrier at least in places. This means, that the reflective layer can be applied in places on the carrier. The reflective layer can also be applied to all exposed surfaces, in particular of the carrier, the optoelectronic semiconductor chip and possibly a temporary medium.

According to at least one embodiment of the method for producing an optoelectronic semiconductor chip, the method comprises a method step in which the optoelectronic semiconductor chip is at least partially molded with a housing, which comprises a molded body. The housing can, for example, comprise a molded body made of a molding compound. The housing can be adapted to the semiconductor chip by molding, injection molding or pressing.

An idea of the method described herein is that due to the applied reflective layer a higher luminance can be achieved, as a lower proportion of the radiation emitted by the optoelectronic semiconductor chip is absorbed by the surrounding housing and can instead be emitted in a preferred direction of radiation. Furthermore, the reflective layer can at least partially protect the housing material from irradiation with the emitted electromagnetic radiation. As a result, the service life of the optoelectronic component can be extended and it can thus be operated efficiently.

According to at least one embodiment of the method for producing an optoelectronic semiconductor chip, a temporary medium is applied to the optoelectronic semiconductor chip prior to the application of the reflective layer. The temporary medium may comprise a lacquer. The temporary medium can, for example, be applied to the optoelectronic semiconductor chip by vapor deposition, coating, sputtering, dispensing and/or stamping. In particular, the temporary medium can be applied only to the side of the optoelectronic semiconductor chip facing away from the carrier. Furthermore, the temporary medium can be applied to the optoelectronic semiconductor chip before or after the optoelectronic semiconductor chip is applied to the carrier.

The temporary medium can be removed by wet blasting, for example. An advantage of using a temporary medium is that the optoelectronic semiconductor chip is protected on the side facing the temporary medium.

According to at least one embodiment of the method for producing an optoelectronic semiconductor chip, the reflective layer is applied directly to the at least one side surface of the optoelectronic semiconductor chip and the side surface extends transversely or perpendicularly to the main extension plane of the carrier. Possible methods for applying the reflective layer to the optoelectronic semiconductor chip are, for example, vapor deposition or sputtering. Due to the direct contact of the reflective layer with the optoelectronic semiconductor chip the component size can be minimized, or at least reduced. Further, as a result, a higher luminance can be achieved. The reflective layer can also be applied directly to the at least one side surface using standard processes. The side surface, which runs transverse or perpendicular to the main extension plane of the carrier, is a surface from which the emission of electromagnetic radiation is not intended. Advantageously, radiation emerging from the side surface is reflected at the reflective layer.

According to at least one embodiment of the method for producing an optoelectronic semiconductor chip, the reflective layer completely covers the carrier with the optoelectronic semiconductor chip after application.

Thereby, completely means that the reflective layer is applied to all exposed surfaces of the carrier with the optoelectronic semiconductor chip as a continuous coating, for example by vapor deposition or sputtering. Completely can thereby also mean that the reflective layer is also arranged on the side surfaces of the optoelectronic semiconductor chip.

For example, the reflective layer is not removed from the carrier after application, at least in places or completely. The reflective layer can cover the carrier in the finished optoelectronic semiconductor chip, for example, at least in places. For example, the reflective layer is in direct contact with the carrier.

An idea of this method step is to apply a reflective layer to the surface of the optoelectronic semiconductor chip. An advantage of this embodiment is that the reflective layer does not have to be applied selectively to individual areas, but the entire surface is completely covered. This simplifies the application process.

According to at least one embodiment of the method for producing an optoelectronic semiconductor chip, the housing completely surrounds the optoelectronic semiconductor chip at least on the side surfaces which extend transversely or perpendicularly to the main extension plane of the carrier.

The housing may only completely surround the side surfaces of the optoelectronic semiconductor chip that extend transversely or perpendicularly to the main extension plane of the carrier. It is further conceivable that also the top side of the optoelectronic semiconductor chip, which extends parallel to the main extension plane of the carrier, is also surrounded by the housing. Surrounded here means that the housing is arranged around the optoelectronic semiconductor chip. It is possible that only the reflective layer is located between the housing and the semiconductor chip.

According to at least one embodiment of the method for producing an optoelectronic semiconductor chip, the side of the optoelectronic semiconductor chip facing away from the carrier is exposed after molding with the housing. The temporary medium, a part of the reflective layer and/or a part of the housing may be located on the side of the optoelectronic semiconductor chip facing away from the carrier. For example, on the side of the optoelectronic semiconductor chip facing away from the carrier, there may first be a part of the reflective layer and then a part of the housing on top. The housing and the reflective layer can be removed from the side of the optoelectronic semiconductor chip facing away from the carrier by means of mechanical processing, for example by grinding or water abrasion. Alternatively, the optoelectronic semiconductor chip can also be completely surrounded by the housing in lateral directions only. Accordingly, for example, the temporary medium and then a part of the reflective layer are applied to the side of the optoelectronic semiconductor chip facing away from the carrier. The side of the optoelectronic semiconductor chip facing away from the carrier can then be exposed, for example by water abrasion/wet blasting. An advantage of the method step described above is that, for example, no mask is required to apply the reflective layer and the housing. Thus, the method steps of applying the reflective layer and the housing are uncomplicated. In addition, the coating can be uncomplicatedly removed together with the temporary medium.

According to at least one embodiment of the method for producing an optoelectronic semiconductor chip, the side of the optoelectronic semiconductor chip facing away from the carrier is exposed prior to molding with the housing. Exposing may include removing the reflective layer. The reflective layer can be removed by wet blasting. Subsequently, the optoelectronic semiconductor chip can be molded with a molding compound. According to this embodiment, the housing can be arranged up to the edge of the emitting or irradiated surface of the optoelectronic semiconductor chip. The side of the optoelectronic semiconductor chip facing away from the carrier can be free of the housing. An advantage of this embodiment is that less material has to be removed from the side of the optoelectronic semiconductor chip facing away from the carrier by means of wet blasting. Furthermore, this embodiment comprises a low material consumption of the housing material.

According to at least one embodiment of the method for producing an optoelectronic semiconductor chip, the method is carried out for a plurality of further optoelectronic semiconductor chips on the carrier and the carrier is cut. Each further optoelectronic semiconductor chip may comprise the same features as the optoelectronic semiconductor chip. That the carrier is cut can mean that the carrier with the optoelectronic semiconductor chip and the further optoelectronic semiconductor chips is singulated into a plurality of optoelectronic components. An idea of this embodiment is to produce a plurality of optoelectronic components particularly efficiently. An advantage is that a plurality of optoelectronic components can be manufactured in parallel.

According to at least one embodiment of the method for producing an optoelectronic semiconductor chip, prior to the application of the reflective layer, the gap formed between the carrier and the side of the optoelectronic semiconductor chip facing the carrier is at least partially filled with an electrically insulating filling material. The filling material can, for example, be inserted into the gaps by means of a spraying process and/or with the help of capillary forces. The filling material prevents a short-circuit of the optoelectronic component via the reflective layer by filling the gaps formed by the electrical contacting and the optoelectronic semiconductor chip. The exposed sides of the filling material can be at least partially, in particular completely, covered with the reflective layer when the reflective layer is subsequently applied. In particular, the reflective layer can be directly adjacent to the filling material. For example, the reflective layer is subsequently not removed from the filling material and/or the carrier, at least in places or completely. The reflective layer can thus, for example, be directly adjacent to the filling material in the optoelectronic semiconductor chip produced using the method. For example, the reflective layer completely covers the filling material on the sides that are exposed prior to the application of the reflective layer.

In the following, the optoelectronic component described herein and the method for producing an optoelectronic component described herein are explained in more detail in connection with exemplary embodiments and the associated figures.

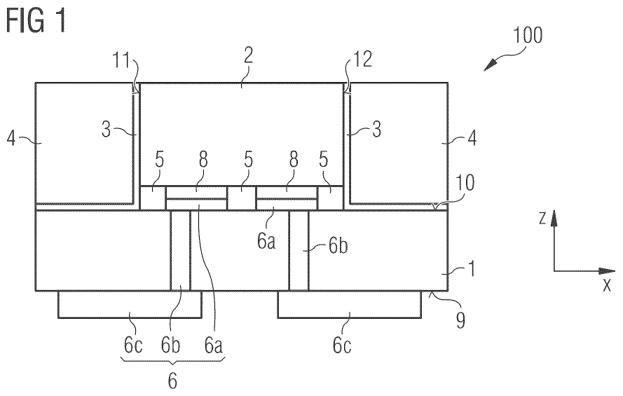

FIG. 1 shows a schematic cross-section of an optoelectronic component according to an exemplary embodiment.

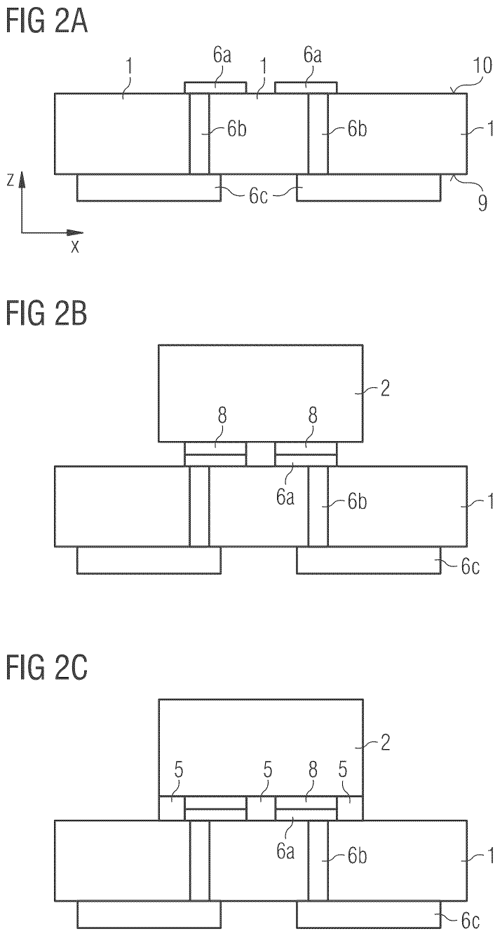

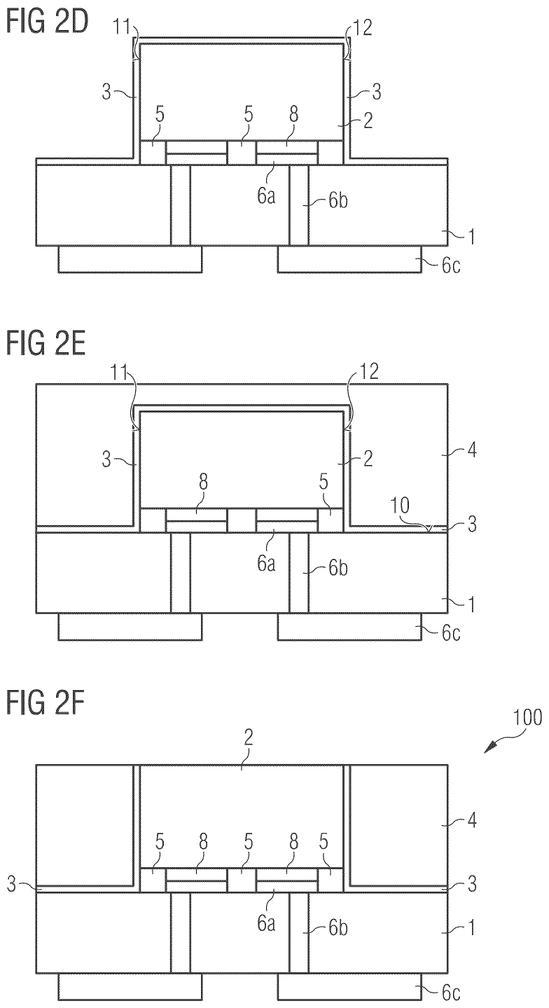

FIGS. 2A, 2B, 2C, 2D, 2E and 2F show method steps in a method for producing an optoelectronic component according to an exemplary embodiment.

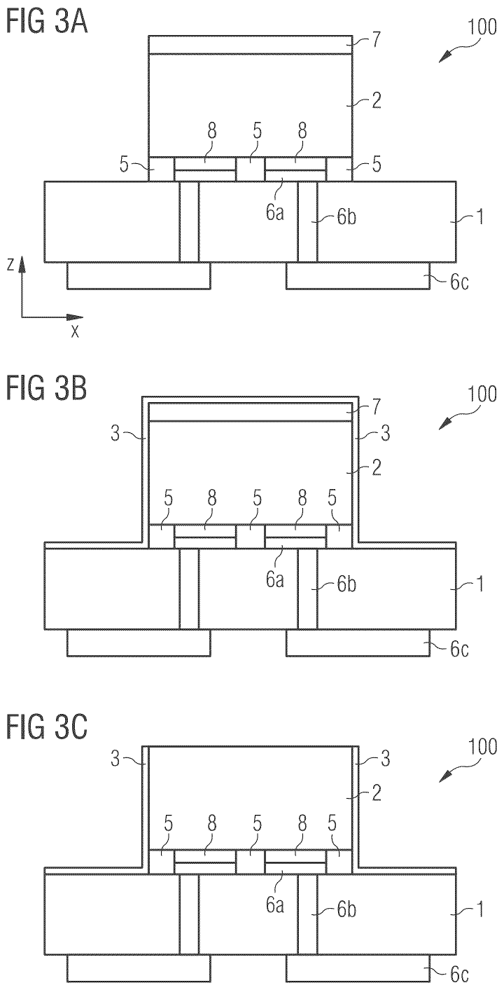

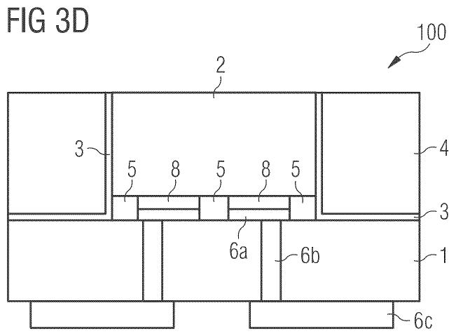

FIGS. 3A, 3B, 3C and 3D show steps in a process for producing an optoelectronic component according to a further exemplary embodiment.

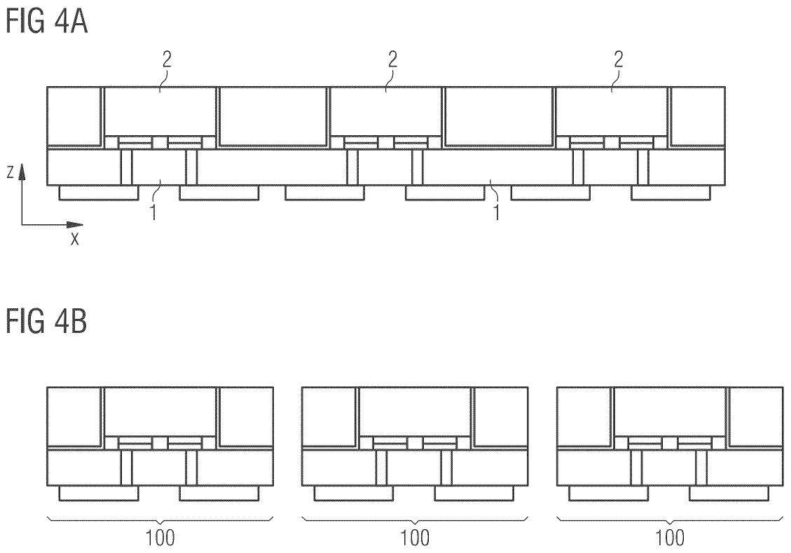

FIGS. 4A and 4B show a further embodiment of a method for producing an optoelectronic component.

Elements that are identical, similar or have the same effect are marked with the same reference signs in the figures. The figures and the proportions of the elements shown in the figures are not to be regarded as being true to scale.

Rather, individual elements may be shown exaggeratedly large for better visualization and/or better comprehensibility.

FIG. 1 shows a sectional view of an optoelectronic component 100. The optoelectronic component 100 comprises a carrier 1. The carrier 1 comprises two vias 6b that extend completely through the carrier 1. Two contact regions 6a are arranged spaced apart from one another on the top side 10 of the carrier 1. On the underside 9 of the carrier 1 there are two connection regions 6c, which are arranged spaced apart from one another. The contact regions 6a, the vias 6b and the connection regions 6c together form an electrical contacting 6. Each of the connection regions 6c on the underside 9 of the carrier 1 is electrically connected to a contact region 6a on a top side 10 of the carrier 1 via one of the vias 6b. The top side 10 is arranged on a side of the carrier 1 facing away from the underside 9.

The optoelectronic component 100 comprises an optoelectronic semiconductor chip 2 which is applied to the carrier 1. The optoelectronic semiconductor chip 2 can be designed to emit electromagnetic radiation in the ultraviolet range during operation. The optoelectronic semiconductor chip 2 comprises two solder pads 8 on its side facing the carrier 1. The solder pads 8 are each electrically conductive connected to the contact regions 6a of the carrier 1. An electrically non-conductive filling material 5 is inserted in the gaps between the optoelectronic semiconductor chip 2 and the carrier 1. As in the exemplary embodiment shown here, this can be flush with the edges of the optoelectronic semiconductor chip 2. Alternatively, the filling material 5 can, for example, also extend beyond the edges of the optoelectronic semiconductor chip 2 or partially cover a side surface 11 of the optoelectronic semiconductor chip 2. The optoelectronic semiconductor chip 2 comprises at least one side surface 11 and at least one further side surface 12, which extend transversely or perpendicularly to the main extension plane of the carrier 1. The side surface 11 and the further side surface 12 can be seen in the sectional view in FIG. 1. However, the optoelectronic semiconductor chip 2 can comprise even more side surfaces 11, 12, for example a total of four. In the exemplary embodiment shown here, a reflective layer 3 is applied directly to the side surfaces 11, 12 of the optoelectronic semiconductor chip 2 and covers them completely. The reflective layer 3 comprises a metal, aluminum, rhodium and/or a mirror. The reflective layer 3 may comprise a reflectivity of at least 40% in the UV range. Furthermore, in this exemplary embodiment, the reflective layer 3 is also arranged in places directly on the filling material 5 adjacent to the side surfaces 11, 12 and in places directly on the carrier 1. The reflective layer 3 covers regions of the carrier 1 which are free of the optoelectronic semiconductor chip 2. The optoelectronic semiconductor chip 2 is completely surrounded by a housing 4 in lateral directions x, which extend parallel to the main extension plane of the carrier 1, wherein the housing 4 is in direct contact with the reflective layer 3. The housing 4 comprises a molded body. The housing 4 is arranged on the carrier 1. Thus, some regions of the reflective layer 3 are arranged between the carrier 1 and the housing 4 in a vertical direction z, which extends perpendicularly to the main extension plane of the carrier 1.

In the schematic sectional views of FIGS. 2A to 2F, an exemplary embodiment of a method for producing an optoelectronic component 100 is shown.

In a first step, FIG. 2A, the carrier 1 is provided. Two contact regions 6a are located on the top side 10 of the carrier 1 and two connection regions 6c are located on the underside 9 of the carrier 1. A connection region 6c is each connected to a contact region 6a by means of an electrically conductive via 6b through the carrier 1. Since FIGS. 2A to 2F are schematic sectional views, the three parts of the carrier 1 shown can in particular be connected to each other.

In the next step, FIG. 2B, the optoelectronic semiconductor chip 2 is soldered onto the contact regions 6a on the carrier 1 by means of solder pads 8.

FIG. 2C shows the optoelectronic component 100 after a method step in which the filling material 5 is inserted into the gaps between the optoelectronic semiconductor chip 2 and the carrier 1. The filling material 5 prevents a short-circuit of the optoelectronic semiconductor chip 2 through the reflective layer 3.

Subsequently, FIG. 2D, the reflective layer 3 is applied onto the optoelectronic component 100. The reflective layer 3 covers the side surfaces 11, 12 of the optoelectronic semiconductor chip 2, the exposed surfaces of the filling material 5 and partially the top side 10 of the carrier 1.

As shown in FIG. 2E, this is followed by a next step in the method for producing an optoelectronic component 100, in which the optoelectronic semiconductor chip 2 is molded with the housing 4. This encloses the optoelectronic semiconductor chip 2 and enables a mechanically robust component. The housing 4 covers the regions of the carrier 1 that are free of the optoelectronic semiconductor chip 2 and the optoelectronic semiconductor chip 2 completely. The housing 4 completely surrounds the optoelectronic semiconductor chip 2 on the side surfaces 11, 12, which extend transversely or perpendicularly to the main extension plane of the carrier 1.

FIG. 2F shows a cross-section of a finished optoelectronic component 100. After the application of the housing 4 in FIG. 2E, a surface of the optoelectronic semiconductor chip 2 facing away from the carrier 1 is exposed. The exposed surface is intended to emit radiation during operation of the optoelectronic component 100.

In the schematic sectional views of FIGS. 3A to 3D, a further exemplary embodiment of a method for producing an optoelectronic component 100 is shown. Thereby, the exemplary embodiment shown here follows on from the exemplary embodiment in FIGS. 2A to 2C.

Based on the method steps shown in FIGS. 2A to 2C, a temporary medium 7 is subsequently applied onto the optoelectronic semiconductor chip 2, FIG. 3A. The temporary medium 7 is thereby only applied to the side of the optoelectronic semiconductor chip 2 facing away from the carrier 1.

Subsequently, as shown in FIG. 3B, the reflective layer 3 is applied. The reflective layer 3 covers the temporary medium 7, the side surfaces 11, 12 of the optoelectronic semiconductor chip 2, the exposed surfaces of the filling material 5 and the exposed parts of the top side 10 of the carrier 1.

FIG. 3C shows a subsequent step in which the temporary medium 7 and the reflective layer 3 applied thereto are removed from the side of the optoelectronic semiconductor chip 2 facing away from the carrier 1.

FIG. 3D shows a final method step to complete the optoelectronic component 100, in which the housing 4 is applied in such a way that it laterally molds the optoelectronic semiconductor chip 2. The top side of the housing 4 is flush with the top side of the optoelectronic semiconductor chip 2.

FIG. 4A shows a further embodiment of a method for producing an optoelectronic component 100. Thereby, the method steps described in FIGS. 2A to 2F or 3A to 3D are carried out, wherein the manufacturing method is carried out for a plurality of further optoelectronic semiconductor chips 2 on the carrier 1.

FIG. 4B shows a method step following FIG. 4A, in which the carrier 1 is cut. Thus, a plurality of optoelectronic components 100 can be produced.

The features and exemplary embodiments described in connection with the figures can be combined with one another in accordance with further exemplary embodiments, even if not all combinations are explicitly described. Furthermore, the exemplary embodiments described in connection with the figures may alternatively or additionally comprise further features according to the description in the general part.

The invention is not limited to the description based on the exemplary embodiments. Rather, the invention includes any new feature as well as any combination of features, which includes in particular any combination of features in the patent claims, even if this feature or combination itself is not explicitly stated in the patent claims or exemplary embodiments.

This patent application claims the priority of the German patent application 10 2022 102 431.8, the disclosure of which is hereby incorporated by reference.

### LIST OF REFERENCE SIGNS

1 carrier
2 optoelectronic semiconductor chip
3 reflective layer
4 housing
5 filling material
6 electrical contacting
6a contact region
6b via
6c connection region
7 temporary medium
8 solder pad
9 underside
10 top side
11 side surface
12 further side surface
100 optoelectronic component
x lateral direction
z vertical direction

1. An optoelectronic component comprising:
a carrier,
at least one optoelectronic semiconductor chip, (2 which is arranged on the carrier, and
a housing, which comprises a molded body, wherein the housing at least partially surrounds the optoelectronic semiconductor chip, wherein
a reflective layer is arranged on at least one side surface of the optoelectronic semiconductor chip, and
the carrier comprises vias.

2. The optoelectronic component according to, claim 1, wherein the reflective layer is at least in places in direct contact with the optoelectronic semiconductor chip.

3. The optoelectronic component according to claim 1, wherein the at least one side surface, on which the reflective layer is arranged faces at least a part of the housing.

4. The optoelectronic component according to claim 1, wherein the reflective layer completely covers the at least one side surface of the optoelectronic semiconductor chip.

5. The optoelectronic component according to claim 1, wherein the at least one side surface of the optoelectronic semiconductor chip extends transversely or perpendicularly to the main extension plane of the carrier.

6. The optoelectronic component according to claim 1, in which the optoelectronic semiconductor chip comprises a reflective layer on at least one further side surface, which extends transversely or perpendicularly to the main extension plane of the carrier.

7. The optoelectronic component according to claim 1, wherein the reflective layer is at least in places in direct contact with the housing.

8. The optoelectronic component according to claim 1, wherein the reflective layer comprises a metal, aluminum, rhodium and/or a mirror.

9. The optoelectronic component according to claim 1, in which the optoelectronic semiconductor chip is adapted to emit electromagnetic radiation in the ultraviolet range during operation.

10. The optoelectronic component according to claim 1, wherein the reflective layer comprises a reflectivity of at least 40% in the UV range.

11. The optoelectronic component according to claim 1, wherein the carrier is electrically contactable on the side facing away from the optoelectronic semiconductor chip, and wherein the carrier is covered at least in places with the reflective layer.

12. The optoelectronic component according to claim 1, in which an electrically insulating filling material is arranged between the carrier and the optoelectronic semiconductor chip, wherein the reflective layer is arranged directly at the filling material in places.

13. A method for producing an optoelectronic component with the following steps:
providing a carrier,
applying an optoelectronic semiconductor chip on the carrier,
applying a reflective layer on at least one side surface of the optoelectronic semiconductor chip, and
at least partially molding the optoelectronic semiconductor chip with a housing, (4 which comprises a molded body, wherein
the carrier comprises vias.

14. The method according to claim 13, wherein a temporary medium is applied onto the optoelectronic semiconductor chip prior to the application of the reflective layer.

15. The method according to claim 13, in which the reflective layer is applied directly onto the at least one side surface of the optoelectronic semiconductor chip and the side surface extends transversely or perpendicularly to the main extension plane of the carrier.

16. The method according to claim 13, wherein the reflective layer completely covers the carrier with the optoelectronic semiconductor chip after application.

17. The method according to claim 13, wherein the housing completely surrounds the optoelectronic semiconductor chip at least on the side surfaces, which extend transversely or perpendicularly to the main extension plane of the carrier.

18. The method according to claim 13, wherein the side of the optoelectronic semiconductor chip facing away from the carrier is exposed after molding with the housing.

19. The method according to claim 13, wherein the method is carried out for a plurality of further optoelectronic semiconductor chips on the carrier and the carrier is cut.

20. The method according to claim 13, in which, prior to the application of the reflective layer, the gap, which is formed between the carrier and the side of the optoelectronic semiconductor chip facing the carrier is at least partially filled with an electrically insulating filling material.
